(19) United States
(12) Patent Application Publication
(10) Pub. No.: US 2022/0406781 A1
(43) Pub. Date: Dec. 22, 2022

(54) MEMORY DEVICE USING SEMICONDUCTOR ELEMENT

(71) Applicant: Unisantis Electronics Singapore Pte. Ltd., Singapore (SG)

(72) Inventors: Koji SAKUI, Tokyo (JP); Nozomu HARADA, Tokyo (JP)

(21) Appl. No.: 17/844,935

(22) Filed: Jun. 21, 2022

(30) Foreign Application Priority Data
Jun. 22, 2021 (JP) PCT/JP2021/023532

(51) Int. Cl. H01L 27/108

(52) U.S. Cl. CPC H01L 27/10802; H01L 27/10805

(57) ABSTRACT

A memory device includes a page made up of plural memory cells arranged in a column on a substrate, and a page write operation is performed to hold positive hole groups generated by an impact ionization phenomenon, in a channel semiconductor layer by controlling voltages applied to a first gate conductor layer, a second gate conductor layer, a first impurity region, and a second impurity region of each memory cell contained in the page and a page erase operation is performed to remove the positive hole groups out of the channel semiconductor layer by controlling voltages applied to the first gate conductor layer, the second gate conductor layer, the first impurity region, and the second impurity region. The first impurity layer of the memory cell is connected with a source line, the second impurity layer is connected with a bit line, one of the first gate conductor layer and the second gate conductor layer is connected with a word line, and another is connected with a drive control line. During a refresh operation, at least one of word lines is selected and a voltage of the channel semiconductor layer of the selected word line is returned to a voltage in a state in which a page is written by controlling voltages applied to the selected word line, the drive control line, the source line, and the bit line and thereby forming the positive hole groups by an impact ionization phenomenon in the channel semiconductor layer.

### CROSS-REFERENCE TO RELATED APPLICATIONS

This application claims priority under 35 U.S.C. § 119(a) to PCT/JP2021/023532 filed Jun. 22, 2021, the enter content of which is incorporated herein by reference.

### TECHNICAL FIELD

The present invention relates to a memory device using a semiconductor element.

### BACKGROUND ART

In recent years, there has been demand for greater packaging density and higher performance in LSI (Large Scale Integration) technology development.

With a typical planar MOS transistor, a channel extends in a horizontal direction along an upper surface of a semiconductor substrate. In contrast, a channel of an SGT extends in a direction perpendicular to an upper surface of a semiconductor substrate (see, for example, Patent Literature 1 and Non Patent Literature 1). Consequently, the SGT enables greater packaging density of semiconductor devices than does the planar MOS transistor. The use of the SGT as a select transistor enables high integration of a DRAM (Dynamic Random Access Memory; see, for example, Non Patent Literature 2) connected with a capacitor, a PCM (Phase Change Memory; see, for example, Non Patent Literature 3) connected with a variable resistance element, an RRAM (Resistive Random Access Memory; see, for example, Non Patent Literature 4), and an MRAM (Magneto-resistive Random Access Memory; see, for example, Non Patent Literature 5) that varies resistance by changing an orientation of a magnetic spin using a current. There is also a capacitorless DRAM memory cell made up of a single MOS transistor (see, for example, Non Patent Literature 7). The present application relates to a dynamic flash memory that can be made up solely of a MOS transistor without a variable resistance element or a capacitor.

FIGS. 7A to 7D show a write operation of the capacitorless DRAM memory cell made up of a single MOS transistor, FIGS. 8A and 8B show problems in operations, and FIGS. 9A to 9C show a read operation (see Non Patent Literatures 7 to 10). FIG. 7A shows a 1-written state. Here, a memory cell is formed on an SOI substrate 100 and is made up of a source N⁺ layer 103 (hereinafter a semiconductor region containing a high concentration of donor impurities will be referred to as an “N⁺ layer”) connected with a source line SL, a drain N⁺ layer 104 connected with a bit line BL, a gate conductive layer 105 connected with a word line WL, and a floating body 102 of a MOS transistor 110. That is, a DRAM memory cell is made up of a single MOS transistor 110 without a capacitor. Note that a SiO₂ layer 101 of the SOI substrate is placed in contact with an undersurface of the floating body 102. When “1” is written into the memory cell made up of the single MOS transistor 110, the MOS transistor 110 is operated in a saturation region. That is, an electron channel 107 extending from the source N⁺ layer 103 has a pinch-off point 108 and does not reach the drain N⁺ layer 104 connected with a bit line. If the MOS transistor 110 is operated with a gate voltage set to approximately ½ a drain voltage by applying high voltages to the bit line BL connected to the drain N⁺ layer and the word line WL connected to the gate conductive layer 105 as described above, electric field strength is maximized at the pinch-off point 108 in the vicinity of the drain N⁺ layer 104. As a result, accelerated electrons flowing from the source N⁺ layer 103 towards the drain N⁺ layer 104 collide with a Si lattice, and electron-hole pairs are created by kinetic energy lost at that moment (impact ionization phenomenon). Most of the generated electrons (not shown) reach the drain N⁺ layer 104. Only a few very hot electrons reach the gate conductive layer 105 by jumping over a gate oxide film 109. Positive holes 106 generated at the same time charge the floating body 102. In this case, the generated positive holes contribute as an increment to majority carriers because the floating body 102 is made of p-type Si. The floating body 102 is filled with the generated positive holes 106, and if a voltage of the floating body 102 becomes higher than the source N⁺ layer 103 by Vb or more, positive holes generated further are discharged to the source N⁺ layer 103, where Vb is a built-in voltage of a pn junction between the source N⁺ layer 103 and the floating body 102 in a p-layer, and is approximately 0.7 V. FIG. 7B shows how the floating body 102 is charged to saturation by the generated positive holes 106.

Next, a “0” writing operation of a memory cell 110 will be described using FIG. 7C. There are a memory cell 110 that writes “1” and a memory cell 110 that writes “0” randomly to a common select word line WL. FIG. 7C shows how a 1-written state is changed to a 0-written state. To write “0,” the voltage of bit line BL is negatively biased and a pn junction between the drain N⁺ layer 104 and the floating body 102 in the p-layer is forward biased. As a result, positive holes 106 generated in the floating body 102 beforehand in the previous cycle flows to the drain N⁺ layer 104 connected to the bit line BL. Once the write operation finishes, two states of the memory cell follow: a state in which the memory cell 110 is filled with the generated positive holes 106 (FIG. 7B) and a state in which the generated positive holes are discharged from the memory cell 110 (FIG. 7C). The floating body 102 of the memory cell 110 filled with the positive holes 106 is higher in potential than the floating body 102 free of generated positive holes. Therefore, a threshold voltage of the memory cell 110 written with “1” is lower than a threshold voltage of the memory cell 110 written with “0.” FIG. 7D shows how this looks like.

Next, problems in operations of a memory cell made up of the single MOS transistor 110 will be described using FIGS. 8A and 8B. As shown in FIG. 8A, capacitance C_{FB} of the floating body is the sum total of capacitance C_{WL} between a gate connected with a word line and the floating body, junction capacitance C_{SL} of a pn junction between the source N⁺ layer 103 connected with a source line and the floating body 102, and junction capacitance C_{BL} of a pn junction between the drain N⁺ layer 104 connected with the bit line and the floating body 102; and is given by

C_{FB}=C_{WL}+C_{BL}+C_{SL} (10)

A capacitive coupling ratio β_{WL} between the gate connected with a word line and the floating body is given by

β_{WL}=C_{WL}/(C_{WL}+C_{BL}+C_{SL}) (11)

Therefore, if a word line voltage V_{WL} swings during reading or writing, a voltage of the floating body 102 serving as a memory node (contact) of the memory cell is also affected. FIG. 8B shows how this looks like. If a word line voltage V_{WL} rises from 0 V to V_{WLH} during reading or writing, a voltage V_{FB} of the floating body 102 rises from V_{FB1} to V_{FB2} due to capacitive coupling with the word line, where V_{FB1} is an initial voltage before the word line voltage changes. The amount of change ΔV_{FB} in voltage is given by

ΔV_{FB}=VF_{B2}−V_{FB}1=β_{WL}×V_{WLH} (12)

In β_{WL} in Eq. (11), a contribution ratio of C_{WL} is large, and is expressed, for example, by C_{WL}:C_{BL}:C_{SL}=8:1:1. In this case, β_{WL}=0.8. If the word line, for example, is 5 V during writing and 0 V after the end of writing, due to capacitive coupling of the word line WL and floating body 102, the floating body 102 is subjected to amplitude noise as high as 5 V×β_{WL}=4 V. This poses a problem in that a sufficient margin of potential difference between a logic 1 potential and logic 0 potential of the floating body 102 cannot be secured during writing.

FIGS. 9A to 9C show a read operation, where FIG. 9A shows a 1-written state and FIG. 9B shows a 0-written state. Actually, however, even if Vb is written into the floating body 102 by writing of “1,” if the word line returns to 0 V when the writing is finished, the floating body 102 is lowered to a negative bias. When “0” is being written, because the floating body 102 is negatively biased further, a sufficiently large margin of potential difference cannot be secured between “1” and “0” during writing as shown in FIG. 9C, making it difficult to commercially introduce really capacitorless DRAM memory cells.

### CITATION LIST

### Patent Literature

[Patent Literature 1] Japanese Patent Laid-Open No. 2-188966
[Patent Literature 2] Japanese Patent Laid-Open No. 3-171768
[Patent Literature 3] Japanese Patent No. 3957774

### Non Patent Literature

[Non Patent Literature 1] Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)
[Non Patent Literature 2] H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)
[Non Patent Literature 3] H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)
[Non Patent Literature 4] T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3V,” IEDM (2007)
[Non Patent Literature 5] W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1−9 (2015)
[Non Patent Literature 6] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)
[Non Patent Literature 7] J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)
[Non Patent Literature 8] T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp 1510-1522 (2002).
[Non Patent Literature 9] T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006).
[Non Patent Literature 10] E. Yoshida: “A Capacitorless 1T-DRAM Technology Using Gate-Induced Drain-Leakage (GIDL) Current for Low-Power and High-Speed Embedded Memory,” IEEE IEDM (2006).
[Non Patent Literature 11] J. Y. Song, W. Y. Choi, J. H. Park, J. D. Lee, and B-G. Park: “Design Optimization of Gate-All-Around (GAA) MOSFETs,” IEEE Trans. Electron Devices, vol. 5, no. 3, pp. 186-191, May 2006.
[Non Patent Literature 12] N. Loubet, et al.: “Stacked Nanosheet Gate-All-Around Transistor to Enable Scaling Beyond FinFET,” 2017 IEEE Symposium on VLSI Technology Digest of Technical Papers, T17-5, T230-T231, June 2017.
[Non Patent Literature 13] H. Jiang, N. Xu, B. Chen, L. Zeng1, Y. He, G. Du, X. Liu and X. Zhang: “Experimental investigation of self-heating effect (SHE) in multiple-fin SOI FinFETs,” Semicond. Sci. Technol. 29 (2014) 115021 (7 pp).
[Non Patent Literature 14] E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-69, April 2006.

### SUMMARY OF INVENTION

### Technical Problem

A capacitorless single-transistor DRAM (gain cell) has a problem in that there is large capacitive coupling between a word line and a floating body and if potential of the word line swings during data read or write, the swings are transmitted as noise directly to the floating body. This causes misreading or erroneous rewriting of stored data, making it difficult to put the capacitorless single-transistor DRAM (gain cell) to practical use.

### Solution to Problem

To solve the above problem, a memory device according to the present invention is a memory device that uses a semiconductor element, in which a page is made up of a plurality of memory cells arranged in a row direction of a substrate, and a plurality of the pages is arranged in a column direction,

wherein each of the memory cells contained in each of the pages includes:
a semiconductor base material erected on the substrate in a vertical direction of the substrate or extended on the substrate in a horizontal direction,
a first impurity layer and a second impurity layer provided on opposite ends of the semiconductor base material,
a first gate insulating layer placed in contact with, or close to, the first impurity layer, partially or entirely surrounding a lateral surface of the semiconductor base material between the first impurity layer and the second impurity layer,
a second gate insulating layer joined to the first gate insulating layer and placed in contact with, or close to, the second impurity layer, surrounding the lateral surface of the semiconductor base material,
a first gate conductor layer covering part or all of the first gate insulating layer,
a second gate conductor layer covering the second gate insulating layer, and
a channel semiconductor layer in which the semiconductor base material is covered with the first gate insulating layer and the second gate insulating layer;

a page write operation and a page erase operation are performed by controlling voltages applied to the first gate conductor layer, the second gate conductor layer, the first impurity layer, and the second impurity layer;

the first impurity layer of the memory cell is connected with a source line, the second impurity layer is connected with a bit line, one of the first gate conductor layer and the second gate conductor layer is connected with a word line, and another is connected with a drive control line; and

at least one of word lines is selected and a refresh operation is performed to return a voltage of the channel semiconductor layer to a voltage just after the page write operation by controlling voltages applied to the selected word line, the drive control line, the source line, and the bit line and thereby forming positive hole groups by an impact ionization phenomenon in the channel semiconductor layer of the memory cell subjected to the page write operation (first invention).

In the first invention described above, during the refresh operation, at least one of the word lines is selected by an address latch circuit of a row decoder circuit (second invention).

During the refresh operation, a select-all-word-lines signal is input to the row decoder circuit to select all the word lines in the memory cell block (third invention).

The refresh operation is performed periodically (fourth invention).

The refresh operation is performed periodically using a temperature sensor circuit and a timer circuit (fifth invention).

The drive control line of the memory cells arranged in the row direction and in the column direction is disposed in common to adjacent ones of the memory cells (sixth invention).

First gate capacitance between the first gate conductor layer and the channel semiconductor layer is higher than second gate capacitance between the second gate conductor layer and the channel semiconductor layer (seventh invention).

When viewed in an axial direction of the semiconductor base material, the first gate conductor layer is separated into at least two conductor layers by surrounding the first gate insulating layer.

In the first invention described above, during the page write operation, a positive hole group generated by the impact ionization phenomenon is held in the channel semiconductor layer, and a voltage of the channel semiconductor layer is set to a first data retention voltage higher than a voltage/voltages of one or both of the first impurity layer and the second impurity layer; and

during the page erase operation, by controlling voltages applied to the first impurity layer, the second impurity layer, the first gate conductor layer, and the second gate conductor layer, the positive hole group is pulled out from one or both of the first impurity layer and the second impurity layer, and the voltage of the channel semiconductor layer is set to a second data retention voltage lower than the first data retention voltage (ninth invention).

### BRIEF DESCRIPTION OF DRAWINGS

FIG. 1 is a structural diagram of a memory device having an SGT according to a first embodiment;

FIGS. 2A, 2B and 2C are diagrams explaining effects produced when gate capacitance of a first gate conductor layer 5a connected to a plate line PL of the memory device having the SGT according to the first embodiment is made higher than gate capacitance of a second gate conductor layer 5b connected with a word line WL;

FIGS. 3AA, 3AB and 3AC are diagrams for explaining a write operation mechanism of the memory device having the SGT according to the first embodiment;

FIG. 3B is a diagram for explaining the write operation mechanism of the memory device having the SGT according to the first embodiment;

FIG. 4A is a diagram for explaining a page erase operation mechanism of the memory device having the SGT according to the first embodiment;

FIGS. 4BA, 4BB, 4BC, and 4BD are diagrams for explaining the page erase operation mechanism of the memory device having the SGT according to the first embodiment;

FIG. 4C is a diagram for explaining the page erase operation mechanism of the memory device having the SGT according to the first embodiment;

FIGS. 4DA, 4DB, 4DC and 4DD are diagrams for explaining the page erase operation mechanism of the memory device having the SGT according to the first embodiment;

FIGS. 4EA, 4EB, 4EC and 4ED are diagrams for explaining the page erase operation mechanism of the memory device having the SGT according to the first embodiment;

FIGS. 5A, 5B and 5C are diagrams for explaining a read operation mechanism of the memory device having the SGT according to the first embodiment;

FIG. 6A is a circuit block diagram for explaining a refresh operation of the memory device having the SGT according to the first embodiment;

FIG. 6B is a circuit block diagram for explaining the refresh operation of the memory device having the SGT according to the first embodiment;

FIG. 6C is a circuit block diagram for explaining the refresh operation of the memory device having the SGT according to the first embodiment;

FIG. 6D is an operation waveform diagram for explaining the refresh operation of the memory device having the SGT according to the first embodiment;

FIG. 6E is a circuit block diagram for explaining the refresh operation of the memory device having the SGT according to the first embodiment;

FIG. 6F is a circuit block diagram for explaining the refresh operation of the memory device having the SGT according to the first embodiment;

FIG. 6G is a circuit block diagram for explaining the refresh operation of the memory device having the SGT according to the first embodiment;

FIG. 6H is a circuit block diagram for explaining the refresh operation of the memory device having the SGT according to the first embodiment;

FIGS. 7A, 7B, 7C and 7D are diagrams for explaining a write operation of a capacitorless DRAM memory cell according to a conventional example;

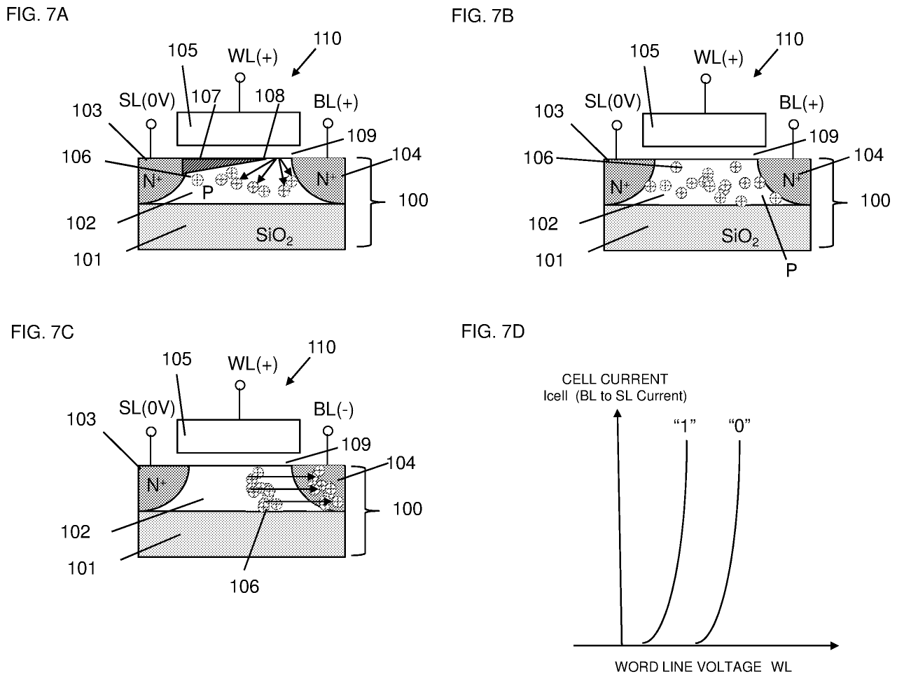

FIGS. 8A and 8B are diagrams for explaining problems in operations of a capacitorless DRAM memory cell according to a conventional example; and

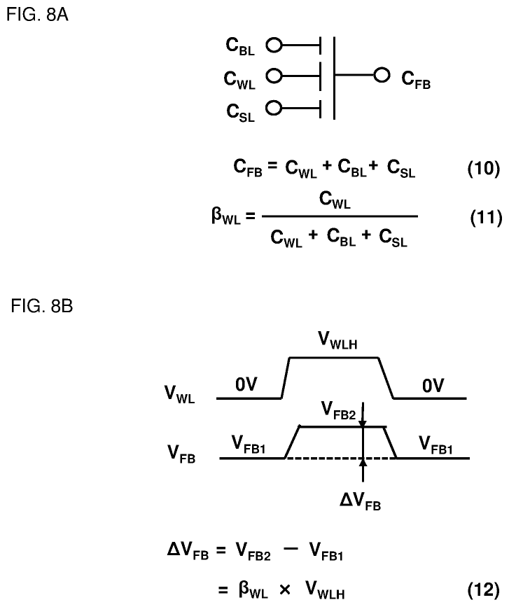

FIGS. 9A, 9B and 9C are diagrams for explaining a read operation of a capacitorless DRAM memory cell according to a conventional example.

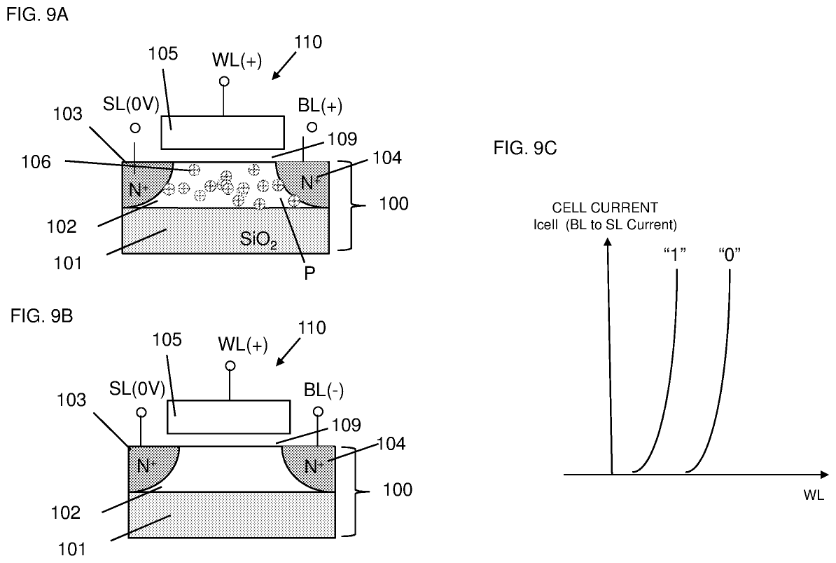

### MODE FOR CARRYING OUT THE INVENTION

Embodiments of a memory device (hereinafter referred to as a dynamic flash memory), which uses a semiconductor element, according to the present invention will be described below with reference to the drawings.

### First Embodiment

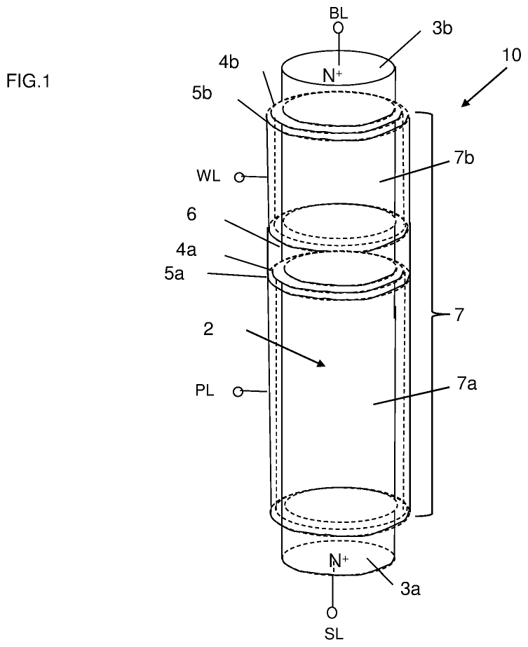

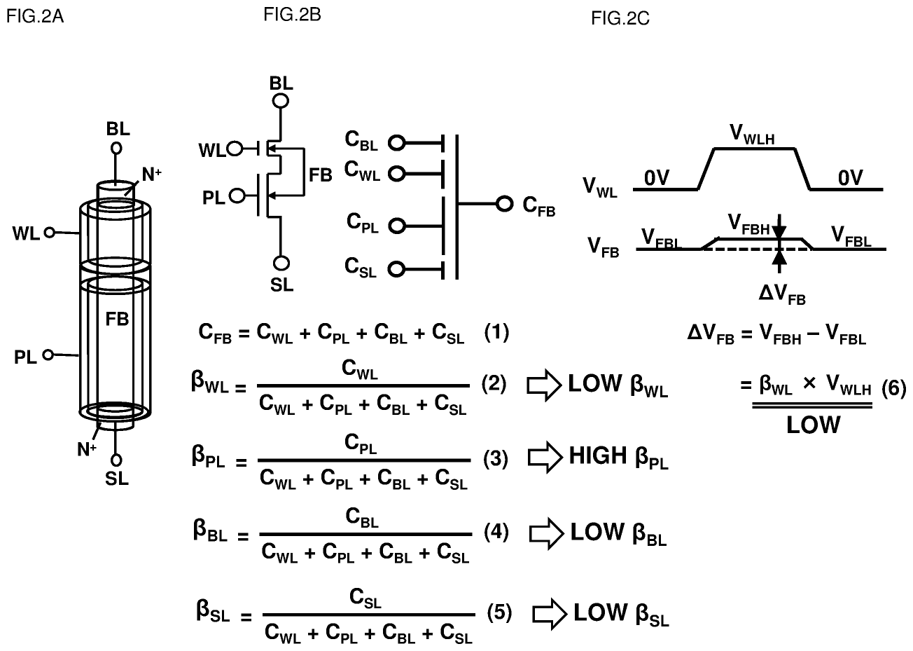

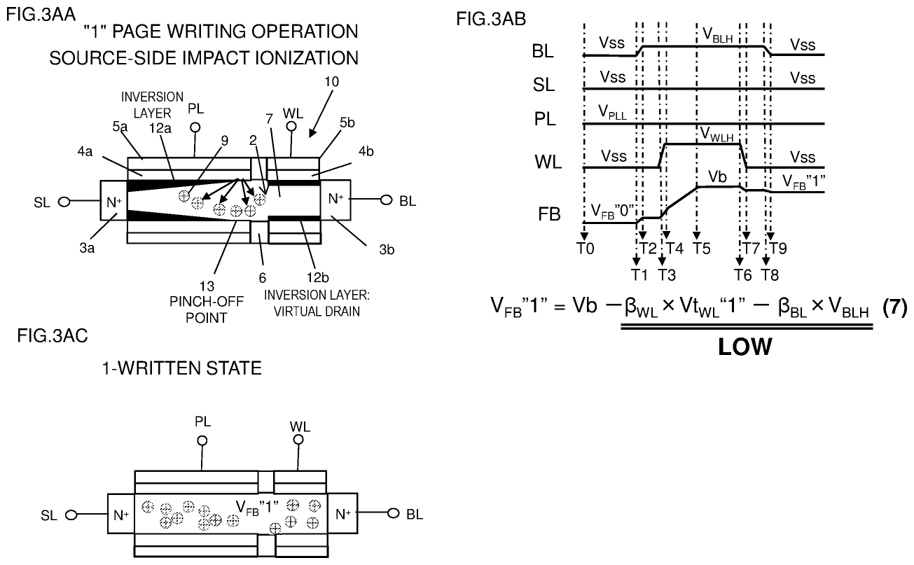

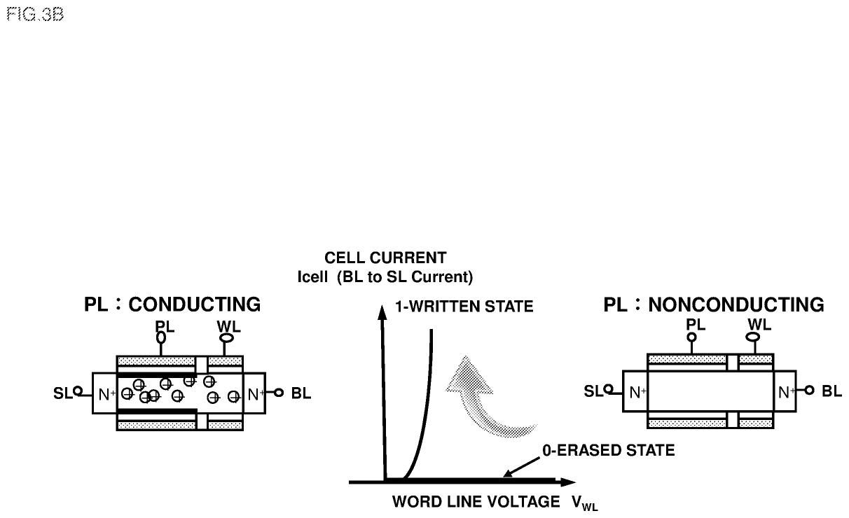

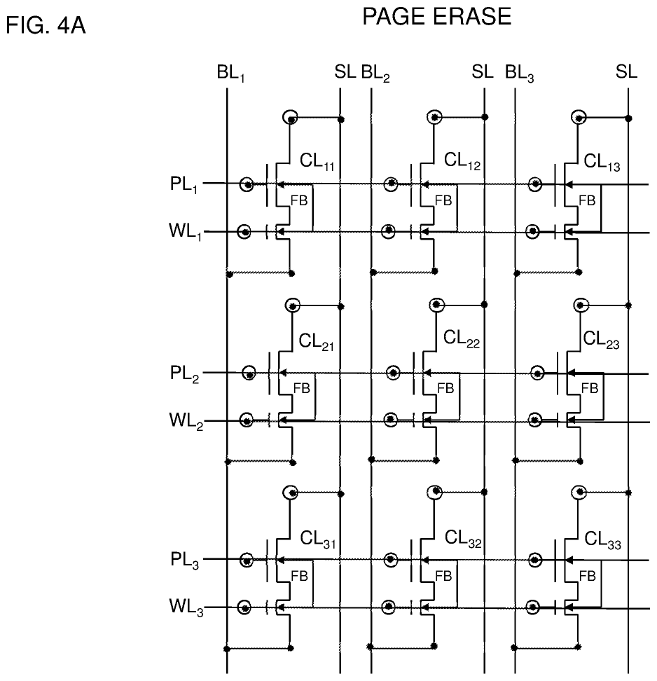

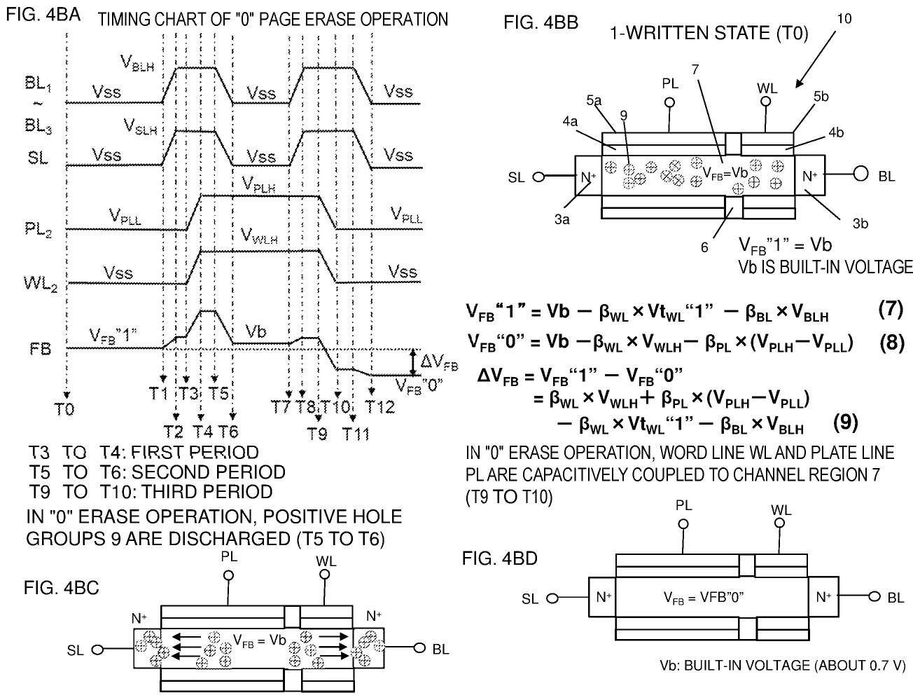

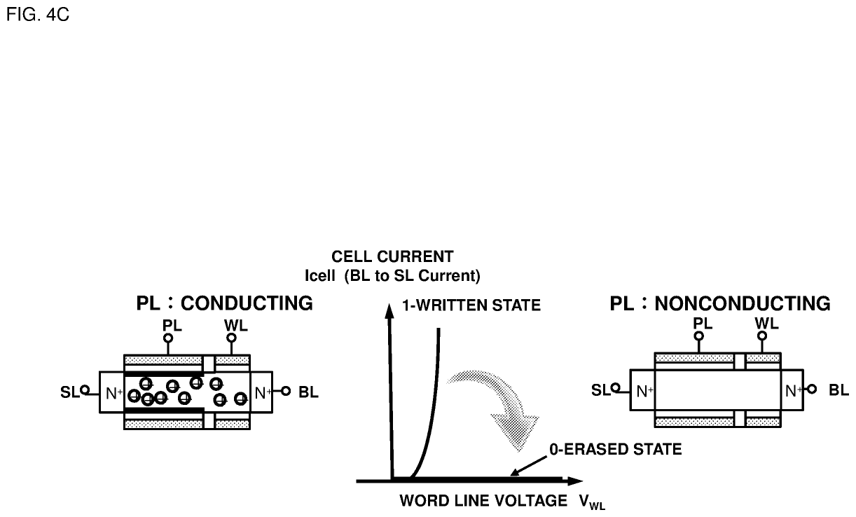

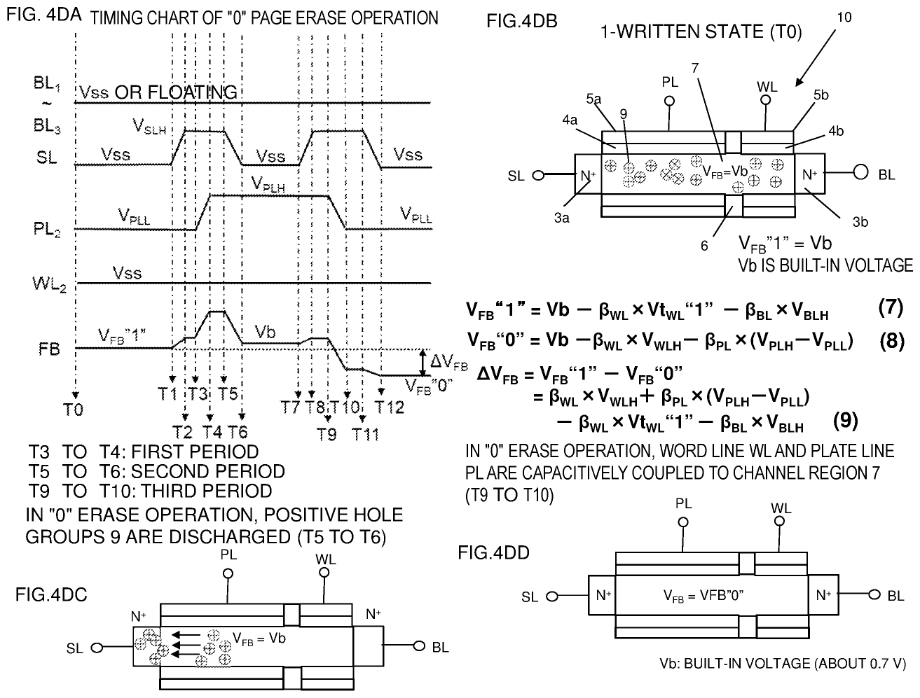

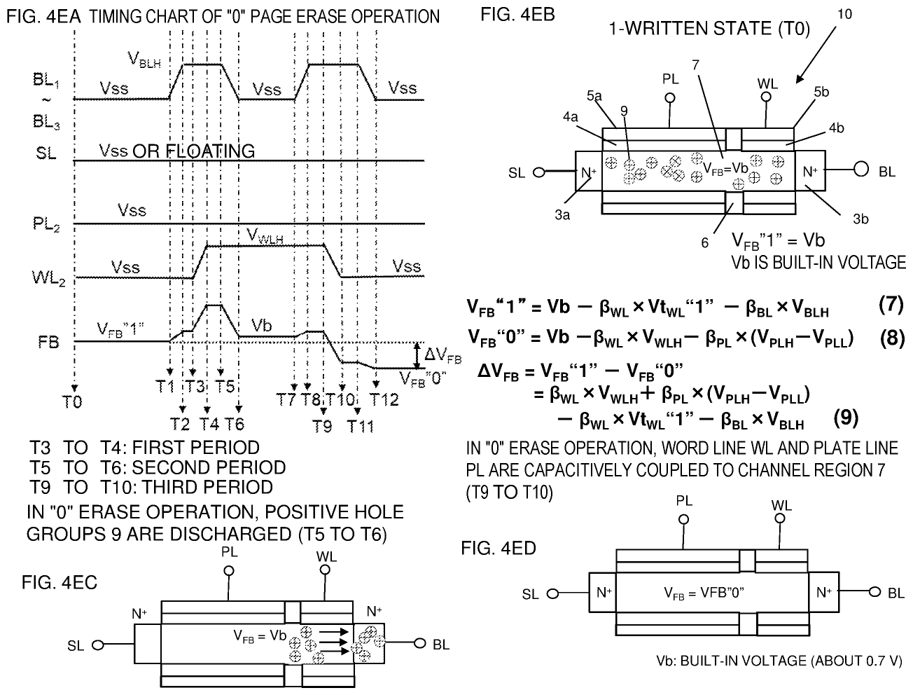

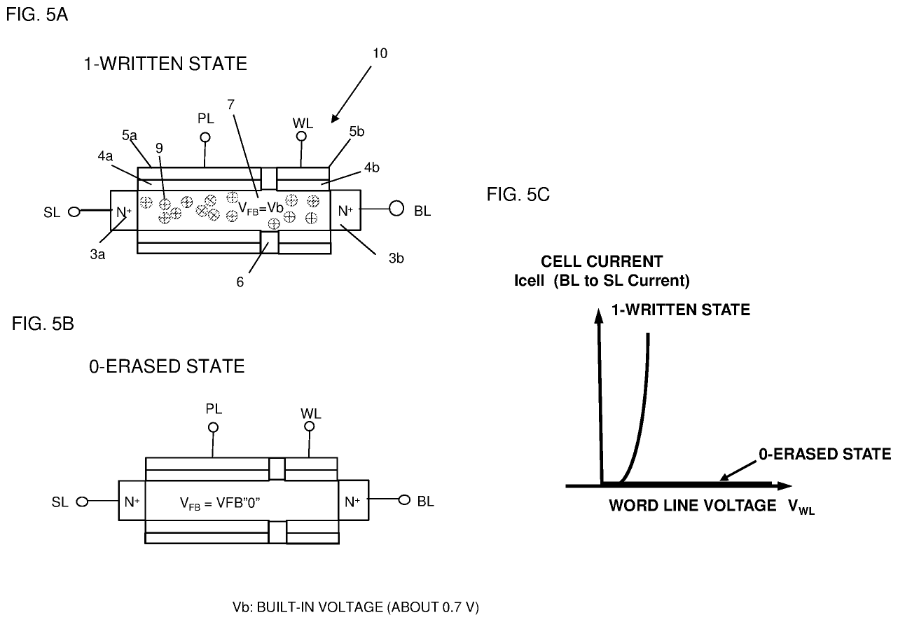

A structure and operation mechanism of a dynamic flash memory cell according to a first embodiment of the present invention will be described below using FIGS. 1 to 5A, 5B and 5C. The structure of the dynamic flash memory cell will be described using FIG. 1. Then, using FIGS. 2A, 2B and 2C, description will be given of effects produced when gate capacitance of a first gate conductor layer 5a connected to a plate line PL is made higher than gate capacitance of a second gate conductor layer 5b connected with a word line WL. Then, a data write operation mechanism will be described using FIGS. 3AA, 3AB, 3AC and 3B, a data erase operation mechanism will be described using FIGS. 4A, 4BA-4BD, 4C, 4DA-4DD and 4EA-4ED, and a data read operation mechanism will be described using FIGS. 5A-5C.

The structure of the dynamic flash memory cell according to the first embodiment of the present invention is shown in FIG. 1. N⁺ layers 3a and 3b (which are examples of a “first impurity layer” and a “second impurity layer” described in Claims), one of which serves as a source while the other serves as a drain, are formed at upper and lower positions in a silicon semiconductor pillar 2 (hereinafter, a silicon semiconductor pillar, which is an example of a “semiconductor base material” described in Claims, will be referred to as a “Si pillar”) formed on a substrate and having a P or i conductivity type (intrinsic type). That part of the Si pillar 2 which is between the N⁺ layers 3a and 3b that serve as the source and the drain is a channel region 7 (which is an example of a “channel semiconductor layer” described in Claims). A first gate insulating layer 4a (which is an example of a “first gate insulating layer” described in Claims) and a second gate insulating layer 4b (which is an example of a “second gate insulating layer” described in Claims) are formed by surrounding the channel region 7. The first gate insulating layer 4a and the second gate insulating layer 4b are placed, respectively, in contact with, or close to, the N⁺ layers 3a and 3b that serve as the source and the drain. The first gate conductor layer 5a (which is an example of a “first gate conductor layer” described in Claims) and the second gate conductor layer 5b (which is an example of a “second gate conductor layer” described in Claims) are formed by surrounding the first gate insulating layer 4a and the second gate insulating layer 4b, respectively. The first gate conductor layer 5a and the second gate conductor layer 5b are separated by an insulating layer 6. The channel region 7 between the N⁺ layers 3a and 3b is made up of a first channel Si layer 7a surrounded by the first gate insulating layer 4a and a second channel Si layer 7b surrounded by the second gate insulating layer 4b. This results in formation of a dynamic flash memory cell 10 made up of the N⁺ layers 3a and 3b, which are to become the source and the drain, the channel region 7, the first gate insulating layer 4a, the second gate insulating layer 4b, the first gate conductor layer 5a, and the second gate conductor layer 5b. Then, the N⁺ layer 3a to become the source is connected to a source line SL (which is an example of a “source line” described in Claims), the N⁺ layer 3b to become the drain is connected to a bit line BL (which is an example of a “bit line BL” described in Claims), the first gate conductor layer 5a is connected to the plate line PL (which is an example of a “drive control line” described in Claims), and the second gate conductor layer 5b is connected to the word line WL (which is an example of a “word line” described in Claims). Desirably the gate capacitance of the first gate conductor layer 5a connected with the plate line PL is structured to be higher than the gate capacitance of the second gate conductor layer 5b connected with the word line WL.

Note that in FIG. 1, the first gate conductor layer 5a is made larger in gate length than the second gate conductor layer 5b such that the first gate conductor layer 5a connected to the plate line PL will be higher in gate capacitance than the second gate conductor layer 5b connected with the word line WL. In addition, however, instead of making the first gate conductor layer 5a larger in gate length than the second gate conductor layer 5b, film thicknesses of the gate insulating layers may be changed such that a gate insulating film of the first gate insulating layer 4a will be smaller in film thickness than a gate insulating film of the second gate insulating layer 4b. Also, materials of the gate insulating layers may be varied in permittivity such that the gate insulating film of the first gate insulating layer 4a will be higher in permittivity than the gate insulating film of the second gate insulating layer 4b. Besides, the first gate conductor layer 5a connected to the plate line PL may be made higher in gate capacitance than the second gate conductor layer 5b connected with the word line WL by combining any of the following: lengths of the gate conductor layers 5a and 5b, and film thicknesses and permittivities of the gate insulating layers 4a and 4b.

FIGS. 2A to 2C are diagrams explaining effects produced when the gate capacitance of the first gate conductor layer 5a connected to the plate line PL is made higher than the gate capacitance of the second gate conductor layer 5b connected with the word line WL.

FIG. 2A is a structural diagram showing only main part the dynamic flash memory cell according to the first embodiment of the present invention in a simplified manner. The dynamic flash memory cell is connected with the bit line BL, the word line WL, the plate line PL, and the source line SL, whose voltage states determine a potential state of the channel region 7.

FIG. 2B is a diagram for explaining relationships among capacitances. Capacitance C_{FB} of the channel region 7 is the sum total of capacitance C_{WL} between the gate conductor layer 5b connected with the word line WL and the channel region 7, capacitance C_{PL} between the gate conductor layer 5a connected with the plate line PL and the channel region 7, junction capacitance C_{SL} of a pn junction between the source N⁺ layer 3a connected with the source line SL and the channel region 7, and junction capacitance C_{BL} of a pn junction between the drain N⁺ layer 3b connected with the bit line BL and the channel region 7, and is given by

C_{FB}=C_{WL}+C_{PL}+C_{BL}+C_{SL} (1)

Therefore, a coupling ratio β_{WL} between the word line WL and the channel region 7, a coupling ratio β_{PL} between the plate line PL and the channel region 7, a coupling ratio β_{BL} between the bit line BL and the channel region 7, a coupling ratio β_{SL} between the source line SL and the channel region 7 are given, respectively, by

β_{WL}=C_{WL}/(C_{WL}+C_{PL}+C_{BL}+C_{SL}) (2)

β_{PL}=C_{PL}/(C_{WL}+C_{PL}+C_{BL}+C_{SL}) (3)

β_{BL}=C_{BL}/(C_{WL}+C_{PL}+C_{BL}+C_{SL}) (4) and

β_{SL}=C_{SL}/(C_{WL}+C_{PL}+C_{BL}+C_{SL}) (5),

where C_{PL}>C_{WL}, and thus β_{PL}>β_{WL}.

FIG. 2C is a diagram for explaining changes of a voltage V_{FB} in the channel region 7 when a voltage V_{WL} of the word line WL rises during read and write operations and falls subsequently. Here, when the voltage V_{WL} of the word line WL rises from 0 V to a high-voltage state V_{WLH} and the voltage V_{FB} of the channel region 7 changes from a low-voltage state V_{FBL} to a high-voltage state V_{FBH}, a potential difference Δ_{VFB} is given by

ΔV_{FB}−V_{FBH}−V_{FBL}−β_{WL}×V_{WLH} (6)

Because the coupling ratio β_{WL} between the word line WL and the channel region 7 is low and the coupling ratio β_{PL} between the plate line PL and the channel region 7 is high, Δ_{VFB} is low and even if the voltage V_{WL} of the word line WL rises and falls during read and write operations, the voltage V_{FB} of the channel region 7 almost does not change.

A memory write operation (which is an example of a “page write operation” described in Claims) of the dynamic flash memory cell according to the first embodiment of the present invention is shown in FIGS. 3AA to 3AC and FIG. 3B. FIG. 3AA shows a mechanism of the write operation and FIG. 3AB shows operation waveforms of the bit line BL, source line SL, plate line PL, word line WL, and channel region 7, which is indicated as the floating body FB. At time T0, the dynamic flash memory cell is in a 0-erased state and the voltage of the channel region 7 is V_{FB} “0.” Besides, Vss is applied to the bit line BL, the source line SL, and the word line WL while V_{PLL} is applied to the plate line PL. Here, for example, Vss is 0 V and V_{PLL} is 2 V. Next, from time T1 to time T2, when the bit line BL rises from Vss to V_{BLH}, for example, if Vss is 0 V, the voltage of the channel region 7 becomes V_{FB} “0”+β_{BL}×V_{BLH} as a result of capacitive coupling between the bit line BL and the channel region 7.

Next, a write operation of the dynamic flash memory cell will be described using FIGS. 3AA and 3AB. From time T3 to time T4, the word line WL rises from Vss to V_{WLH}. Consequently, when the second gate conductor layer 5b connected with the word line WL sets a 0-erasing threshold voltage of a second N-channel MOS transistor region surrounding the channel region 7 to Vt_{WL} “0,” as the voltage of the word line WL rises, from Vss to Vt_{WL}“0,” the voltage of the channel region 7 becomes V_{FB} “0”+β_{BL}×V_{BLH}+β_{WL}×Vt_{WL} “0” as a result of second capacitive coupling between the word line WL and the channel region 7. If the voltage of the word line WL rises to or above Vt_{WL} “0,” an annular inversion layer 12b is formed in the channel region 7 on an inner circumference of the second gate conductor layer 5b, blocking the second capacitive coupling between the word line WL and the channel region 7.

Description of the write operation of the dynamic flash memory cell will be continued using FIGS. 3AA and 3AB. From time T3 to time T4, for example, V_{PLL}=2 V is input constantly to the first gate conductor layer 5a connected with the plate line PL, raising the second gate conductor layer 5b connected with the word line WL to, for example, V_{WLH}=4 V. Consequently, as shown in FIG. 3AA, an annular inversion layer 12a is formed in the channel region 7 on an inner circumference of the first gate conductor layer 5a connected with the plate line PL, with a pinch-off point existing in the inversion layer 12a. As a result, a first N-channel MOS transistor region having the first gate conductor layer 5a operates in a saturation region. On the other hand, the second N-channel MOS transistor region having the second gate conductor layer 5b that is connected with the word line WL operates in a linear region. As a result, no pinch-off point exists in the channel region 7 on the inner circumference of the second gate conductor layer 5b connected with the word line WL, and the inversion layer 12b is formed on the entire inner circumference of the second gate conductor layer 5b. The inversion layer 12b formed on the entire inner circumference of the second gate conductor layer 5b connected with the word line WL operates as a virtual drain of the second N-channel MOS transistor region having the second gate conductor layer 5b that is connected with the word line WL. As a result, an electric field is maximized and an impact ionization phenomenon occurs in a first boundary region of the channel region 7 between the first N-channel MOS transistor region having the first gate conductor layer 5a that is connected in series and the second N-channel MOS transistor region having the second gate conductor layer 5b. The first boundary region is a source-side region viewed from the second N-channel MOS transistor region having the second gate conductor layer 5b that is connected with the word line WL, and thus the phenomenon is called a source-side impact ionization phenomenon. As a result of the source-side impact ionization phenomenon, electrons flow from the N⁺ layer 3a connected with the source line SL toward the N⁺ layer 3b connected with the bit line. Accelerated electrons collide with Si lattice atoms and electron-hole pairs are created by kinetic energy of the accelerated electrons. Part of the generated electrons flows to the first gate conductor layer 5a and the second gate conductor layer 5b, but most of the electrons flow to the N⁺ layer 3b connected to the bit line BL (not shown).

As shown in FIG. 3AC, generated positive hole groups 9 (which are examples of a “positive hole group” described in Claims) are majority carriers in the channel region 7 and charge the channel region 7 so as to be positively biased. The N⁺ layer 3a connected with the source line SL is 0 V and thus the channel region 7 is charged to a built-in voltage Vb (approximately 0.7 V) of a pn junction between the N⁺ layer 3a connected with the source line SL and the channel region 7. Once the channel region 7 is charged to be positively biased, threshold voltages of the first N-channel MOS transistor region and second N-channel MOS transistor region fall due to a substrate bias effect.

Description of the write operation of the dynamic flash memory cell will be continued using FIG. 3AB. From time T6 to time T7, the voltage of the word line WL drops from V_{WLH} to Vss. In so doing, the word line WL and the channel region 7 form the second capacitive coupling, but until the voltage V_{WLH} of the word line WL becomes equal to or lower than the threshold voltage Vt_{WL} “1” of the second N-channel MOS transistor region when the voltage of the channel region 7 is Vb, the inversion layer 12b blocks the second capacitive coupling. Therefore, virtual capacitive coupling between the word line WL and the channel region 7 is enabled only when the word line WL becomes equal to or lower than Vt_{WL} “1” and falls to Vss. As a result, the voltage of the channel region 7 becomes Vb−β_{WL}×Vt_{WL} “1.” Here, Vt_{WL} “1” is lower than Vt_{WL} “0” described above, and thus β_{WL}×Vt_{WL} “1” is low.

Description of the write operation of the dynamic flash memory cell will be continued using FIG. 3AB. From time T8 to time T9, the bit line BL drops from V_{BLH} to Vss. Since the bit line BL and the channel region 7 are capacitively coupled, eventually “1”-writing voltage V_{FB}“1” of the channel region 7 becomes as follows.

V_{FB}“1”=Vb−β_{WL}×Vt_{WL}“1”−β_{BL}×V_{BLH} (7)

where the coupling ratio β_{BL} between the bit line BL and the channel region 7 is also low. Consequently, as shown in FIG. 3B, the threshold voltage of the second N-channel MOS transistor region of a second channel region 7b connected with the word line WL becomes low. A 1-written state of the channel region 7 is set to a first data retention voltage (which is an example of a “first data retention voltage” described in Claims). A memory write operation is performed and this state is assigned to logical storage data “1.”

Note that in the write operation, electron-hole pairs may be generated by an impact ionization phenomenon in a second boundary region between a first impurity layer 3a and a first channel semiconductor layer 7a or in a third boundary region between a second impurity layer 3b and a second channel semiconductor layer 7b rather than in the first boundary region, and the channel region 7 may be charged with the generated positive hole groups 9.

Note that conditions of the voltages applied to the bit lines BL, the source lines SL, the word lines WL, and the plate lines PL as well as the potential of the floating body are exemplary in performing write operations, and other conditions that allow write operations to be performed may be used.

A mechanism of a memory erase operation (which is an example of a “memory erase operation” described in Claims) will be described using FIGS. 4A, 4BA-4BD, 4C, 4DA-4DD and 4EA-4ED.

A memory block circuit diagram is shown in FIG. 4A to explain a page erase operation. Whereas 3 rows by 3 columns of memory cells for a total of nine memory cells CL₁₁ to CL₃₃ are shown here, an actual memory block is larger than this matrix. When memory cells are arrayed in a matrix, one direction of the array is referred to as a “row direction” (or a “row-wise direction”) and a direction perpendicular to the row direction is referred to as a “column direction” (or a “column-wise direction”). The memory cells are connected with the respective source lines SL, bit lines BL₁ to BL₃, plate lines PL₁ to PL₃, and word lines WL₁ to WL₃. For example, it is assumed that in this block, a page erase operation is performed by selecting from memory cells CL₂₁ to CL₂₃ connected with the plate line PL₂ and the word line WL₂ of a desired page (which is an example of a “page” described in Claims).

A mechanism of a page erase operation will be described using FIGS. 4BA to 4BD and 4C. Here, the channel region 7 between the N⁺ layers 3a and 3b is electrically separated from the substrate, making up a floating body. FIG. 4BA shows a timing operation waveform diagram of main nodes of the erase operation. In FIG. 4BA, T0 to T12 indicates times from start to end of the erase operation. FIG. 4BB shows that at time T0 before the erase operation, the positive hole groups 9 generated by impact ionization in the previous cycle are stored in the channel region 7. Then, from time T1 to time T2, the bit lines BL₁ to BL₃ and the source line SL change from Vss to a high-voltage state of V_{BLH} or V_{SLH}. Here, Vss is, for example, 0 V. In this operation from time T3 to time T4 in the next period, the plate line PL₂ and the word line WL₂ selected in the page erase operation go high from a first voltage V_{PLL} to a second voltage V_{PLH} and from a third voltage Vss to a fourth voltage V_{WLH}, thereby preventing the inversion layer 12a on the inner circumference of the first gate conductor layer 5a connected with the plate line PL₂ and the inversion layer 12b on the inner circumference of the second gate conductor layer 5b connected with the word line WL₂ from being formed, respectively, in the channel region 7. Therefore, if the threshold voltages of the second N-channel MOS transistor region on the side of the word line WL₂ and the first N-channel MOS transistor region on the side of the plate line PL₂ are V_{tWL} and V_{tPL}, respectively, preferably the voltages V_{BLH} and V_{SLH} satisfy V_{BLH}>V_{WLH}+V_{tWL} and V_{SLH}>V_{PLH}+V_{tPL}, respectively. For example, if V_{tWL} and V_{tPL} are 0.5 V, V_{WLH} and V_{PLH} can be set to 3 V and V_{BLH} and V_{SLH} can be set to 3.5 V or above.

Description of the page erase operation mechanism in FIG. 4BA will be continued. From time T3 to time T4 in the first period, as the plate line PL₂ and the word line WL₂ go high to the second voltage V_{PLH} and the fourth voltage V_{WLH}, the voltage of the channel region 7 in a floating state is pushed up by first capacitive coupling between the plate line PL₂ and the channel region 7 and second capacitive coupling between the word line WL₂ and the channel region 7. The voltage of the channel region 7 goes high from V_{FB} “1” in a 1-written state. This is because the voltages of the bit lines BL₁ to BL₃ and source line SL are high, namely, V_{BLH} and V_{SLH}, making the pn junction between the N⁺ layer 3a and the channel region 7 and the pn junction between the drain N⁺ layer 3b and the channel region 7 reverse-biased, which enables boosting.

Description of the page erase operation mechanism in FIG. 4BA will be continued. From time T5 to time T6 in the next period, the voltages of the bit lines BL₁ to BL₃ and source line SL drop to Vss from high voltages of V_{BLH} and V_{SLH}. As a result, the pn junction between the N⁺ layer 3a and the channel region 7 and the pn junction between the drain N⁺ layer 3b and the channel region 7 become forward-biased as shown in FIG. 4BC and positive hole groups remaining from the positive hole groups 9 of the channel region 7 are discharged to the source N⁺ layer 3a and the drain N⁺ layer 3b. Consequently, the voltage V_{FB} of the channel region 7 becomes the built-in voltage Vb of the pn junction formed by the source N⁺ layer 3a and the channel region 7 in a p-layer and the pn junction formed by the drain N⁺ layer 3b and the channel region 7 in the p-layer.

Description of the page erase operation mechanism in FIG. 4BA will be continued. Next, from time T7 to time T8, the voltages of the bit lines BL₁ to BL₃ and source line SL go high to V_{BLH} and V_{SLH} from Vss. With this measure, as shown in FIG. 4BD, in lowering the plate line PL₂ and the word line WL₂ from the second voltage V_{PLH} and the fourth voltage V_{WLH} to the first voltage V_{PLL} and the third voltage Vss, respectively, from time T9 to time T10, the voltage V_{FB} of the channel region 7 is changed effectively from Vb to V_{FB} “0” by the first capacitive coupling between the plate line PL₂ and the channel region 7 and the second capacitive coupling between the word line WL₂ and the channel region 7 without forming the inversion layer 12a on the side of the plate line PL₂ and the inversion layer 12b on the side of the word line WL₂ in the channel region 7. Thus, a voltage difference ΔV_{FB} of the channel region 7 between the 1-written state and the 0-erased state is given by the following equations.

V_{FB}“1”=Vb−β_{WL}×Vt_{WL}“1”−β_{BL}×V_{BLH} (7)

V_{FB}“0”=Vb−β_{WL}×V_{WLH}−β_{PL}×(V_{PLH}−V_{PLL}) (8)

ΔV_{FB}=V_{FB}“1”−V_{FB}“0”=β_{WL}×V_{WLH}+β_{PL}×(V_{PLH}−V_{PLL})−β_{WL}×Vt_{WL}“1”−β_{BL}×V_{BLH} (9),

where the sum of β_{WL} and β_{PL} is 0.8 or above, making ΔV_{FB} large enough to provide a sufficient margin.

Consequently, as shown in FIG. 4C, a large margin can be provided between the 1-written state and the 0-erased state. Here, in the 0-erased state, the threshold voltage on the side of the plate line PL₂ is high due to the substrate bias effect. Therefore, if an applied voltage of the plate line PL₂ is set, for example, equal to or lower than the threshold voltage, the first N-channel MOS transistor region on the side of the plate line PL₂ becomes nonconducting and does not pass a memory cell current. “PL: Nonconducting” on the right side of FIG. 4C shows this situation.

Description of the page erase operation mechanism in FIG. 4BA will be continued. Next, from time T11 to time T12 in the fourth period, the voltages of the bit lines BL₁ to BL₃ and source line SL fall to Vss from V_{BLH} and V_{SLH}, respectively, ending the erase operation. In so doing, the bit lines BL₁ to BL₃ and the source line SL lower the voltage of the channel region 7 slightly due to capacitive coupling, but this is equivalent to the amount of the voltage of the channel region 7 raised by the bit lines BL₁ to BL₃ and the source line SL due to capacitive coupling from time T7 to time T8, and thus the raising and lowering of the voltages of the bit lines BL₁ to BL₃ and source line SL are canceled out and consequently the voltage of the channel region 7 is not affected. The voltage V_{FB} “0” of the channel region 7 in the 0-erased state is set to a second data retention voltage (which is an example of a “second data retention voltage” described in Claims). A page erase operation is performed and this state is assigned to logical storage data “0.” During data read after the erase operation, if the voltage to be applied to the first gate conductor layer 5a joined to the plate line PL is set higher than the threshold voltage at a time when the logical storage data is “1” and lower than the threshold voltage at a time when the logical storage data is “0,” the property that no current flows even if the voltage of the word line WL is increased is obtained as shown in FIG. 4C.

Next, a mechanism of the page erase operation will be described using FIGS. 4DA to 4DD. FIGS. 4DA-4DD differs from FIGS. 4BA-4BD in that during the page erase operation the bit lines BL₁ to BL₃ are set to Vss or kept in a floating state and that the word line WL₂ is fixed at Vss. Consequently, from time T1 to time T2, even if the source line SL rises from Vss to V_{SLH}, the second N-channel MOS transistor region of the word line WL₂ remains nonconducting and no memory cell current flows. Thus, there is no generation of positive hole groups 9 due to the impact ionization phenomenon. Besides, as with FIGS. 4BA-4BD, the source line SL swings between Vss and V_{SLH} while the plate line PL₂ swings between V_{PLL} and V_{PLH}. Consequently, as shown in FIG. 4DC, the positive hole groups 9 are discharged to the N⁺ layer 3a of the source line SL.

Next, the mechanism of the page erase operation will be described using FIGS. 4EA to 4ED. FIGS. 4EA-4ED differs from FIGS. 4BA-4BD in that during the page erase operation the source line SL is set to Vss or kept in a floating state and that the plate line PL₂ is fixed at Vss. Consequently, from time T1 to time T2, even if the bit lines BL₁ to BL₃ rise from Vss to V_{BLH}, the first N-channel MOS transistor region of the plate line PL₂ remains nonconducting and no memory cell current flows. Thus, there is no generation of positive hole groups 9 due to the impact ionization phenomenon. Besides, as with FIGS. 4BA-4BD, the bit lines BL₁ to BL₃ swing between Vss and V_{BLH} and the word line WL₂ swings between Vss and V_{WLH}. Consequently, as shown in FIG. 4EC, the positive hole groups 9 are discharged to the N⁺ layers 3b of the bit lines BL₁ to BL₃.

Note that conditions of the voltages applied to the bit lines BL, the source lines SL, the word lines WL, and the plate lines PL as well as the potential of the floating body are exemplary in performing a page erase operation, and other conditions that allow a page erase operation to be performed may be used.

FIGS. 5A to 5C are diagrams for explaining a read operation of the dynamic flash memory cell according to the first embodiment of the present invention. As shown in FIG. 5A, when the channel region 7 is charged to the built-in voltage Vb (approximately 0.7 V), the threshold voltage of the second N-channel MOS transistor region having the second gate conductor layer 5b that is connected with the word line WL drops due to the substrate bias effect. This state is assigned to logical storage data “1.” As shown in FIG. 5B, a memory block selected before a write is set to an erased state “0” in advance and the voltage V_{FB} of the channel region 7 is V_{FB}“0.” As a result of write operations, a written state “1” is stored randomly. As a result, logical storage data of logic “0” and logic “1” is created for the word line WL. As shown in FIG. 5C, using a height difference between two threshold voltages for the word line WL, reading is done by a sense amplifier. During data read, if the voltage to be applied to the first gate conductor layer 5a joined to the plate line PL is set higher than the threshold voltage at a time when the logical storage data is “1” and lower than the threshold voltage at a time when the logical storage data is “0,” the property that no current flows even if the voltage of the word line WL is increased is obtained as shown in FIG. 5C.

Note that conditions of the voltages applied to the bit lines BL, the source lines SL, the word lines WL, and the plate lines PL as well as the potential of the floating body are exemplary in performing read operations, and other conditions that allow read operations to be performed may be used.

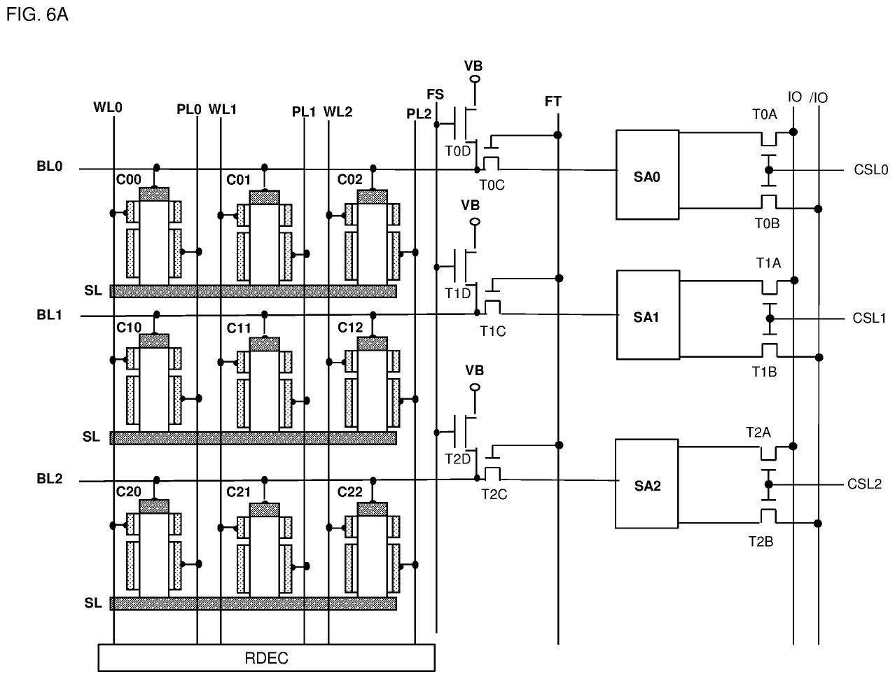

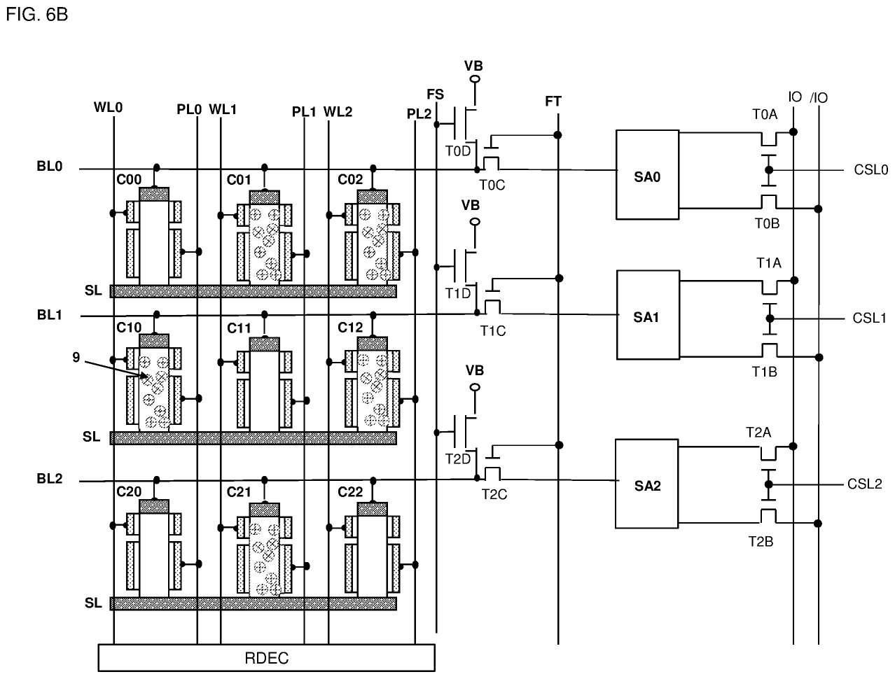

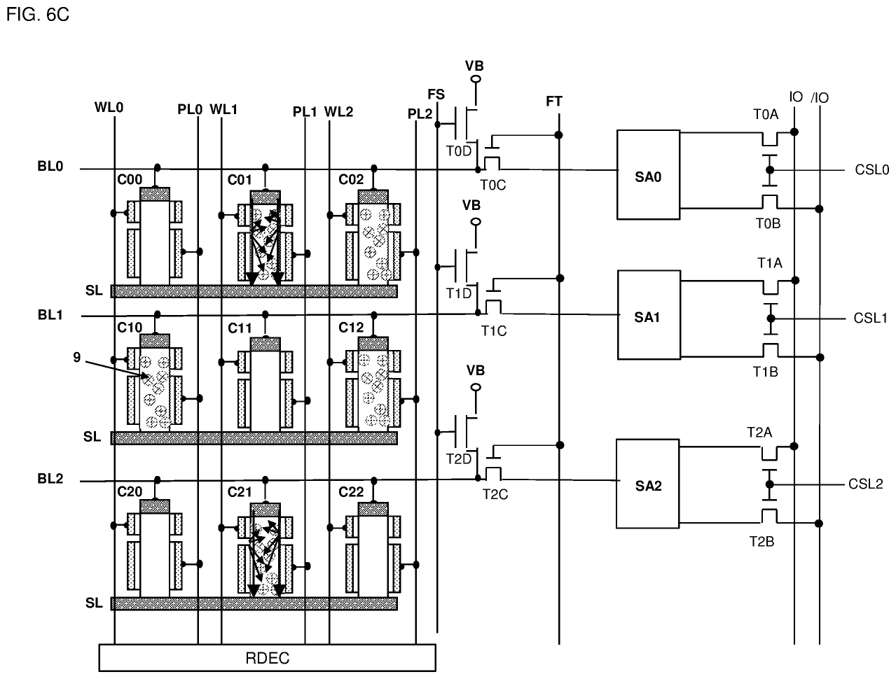

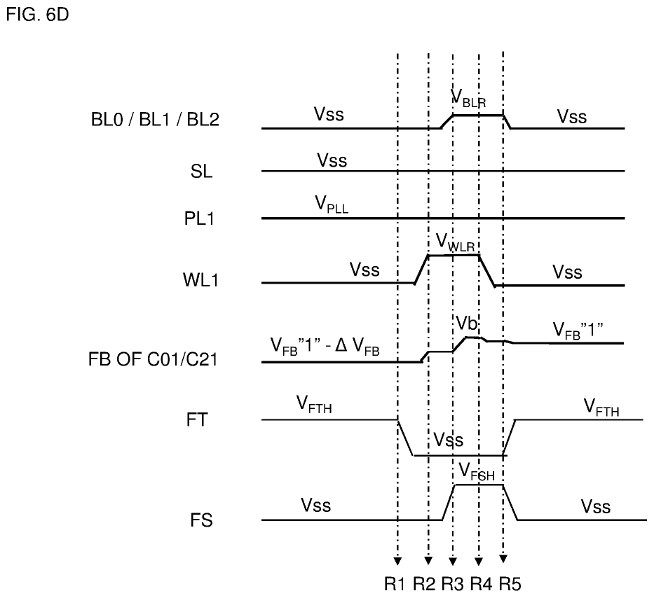

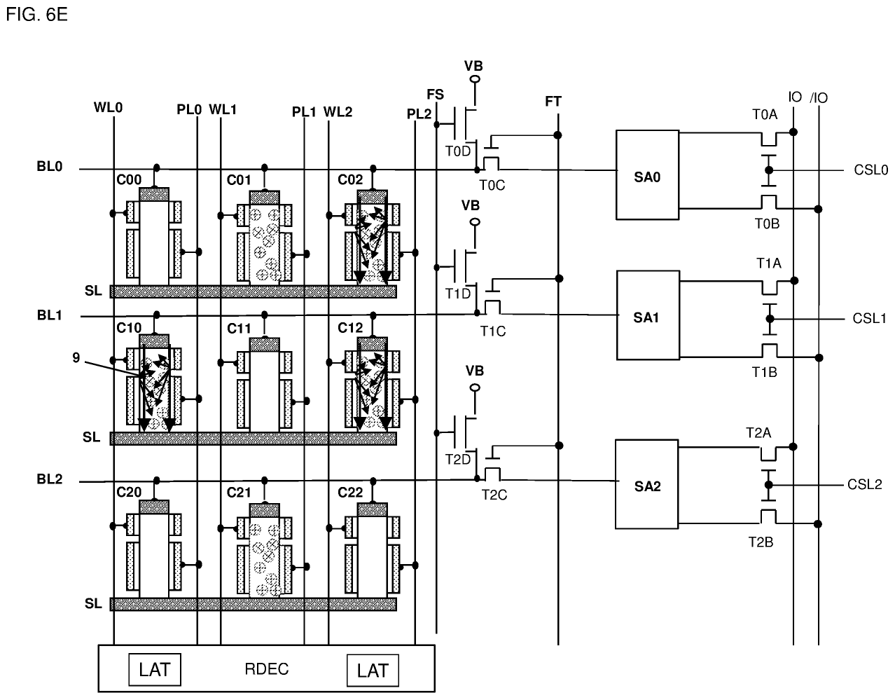

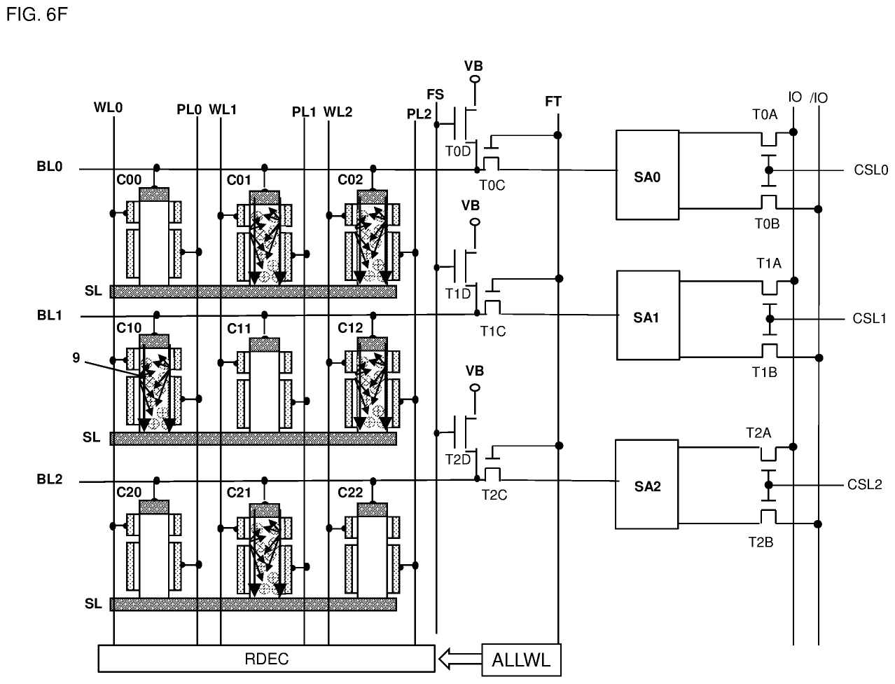

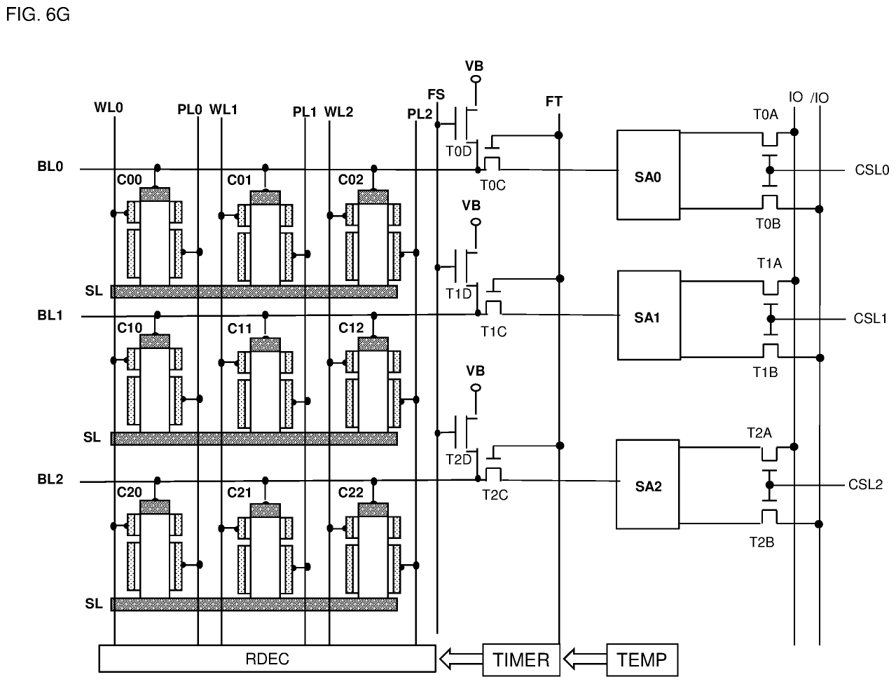

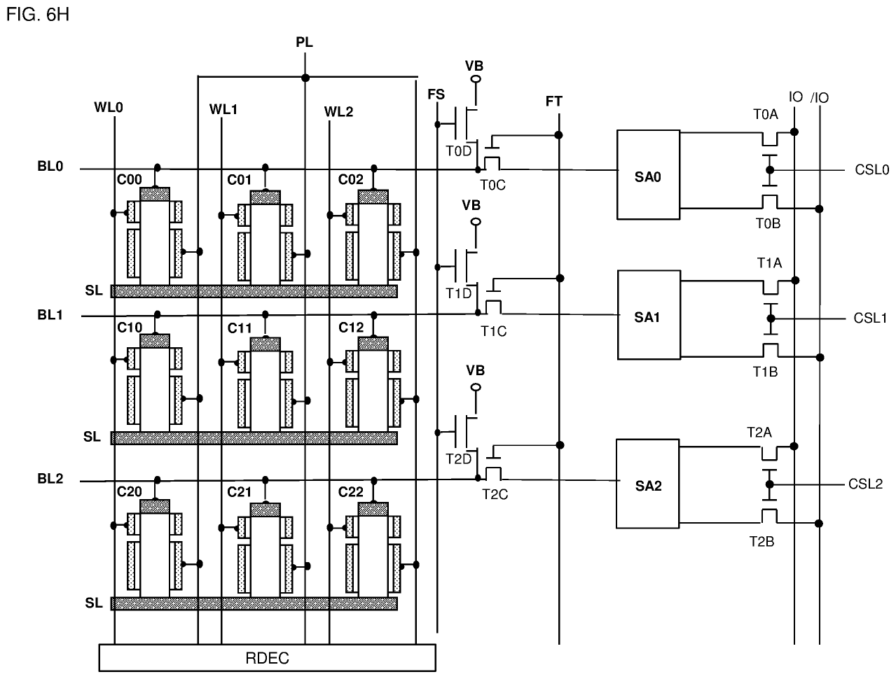

Using FIGS. 6A to 6H, description will be given of a refresh operation (which is an example of a “refresh operation” described in Claims) performed to form positive hole groups in the channel semiconductor layers 7 of the dynamic flash memory cell according to the first embodiment of the present invention by an impact ionization phenomenon and return the voltages of the channel semiconductor layers 7 of selected word lines WL to the first data retention voltage.

In FIG. 6A, three rows by three columns of memory cells C00 to C22 make up part of a memory cell block (which is an example of a “memory cell block” described in Claims). Whereas three rows by three columns of memory cells C00 to C22 are shown here, in an actual memory cell block, memory cells make up a matrix larger than a 3-row by 3-column matrix. The memory cells are connected with respective word lines WL0 to WL₂, plate lines PL0 to PL₂, source lines SL, and bit lines BL0 to BL2. Transistors T0C to T2C to whose gates transfer signals FT are input make up a switch circuit. Also, drains of transistors T0D to T2D whose gates are connected to a bit line precharge signal FS are connected to bit line power supplies VB and sources are connected to the respective bit lines BL0 to BL2. Then, the bit lines BL0 to BL2 are connected to respective sense amplifier circuits SA0 to SA2 via switch circuits. The word lines WL0 to WL₂ and the plate lines PL0 to PL₂ are connected to a row decoder circuit (which is an example of a “row decoder circuit” described in Claims) RDEC. The sense amplifier circuits SA0 to SA2 are connected to a pair of input-output lines IO and/IO complementary to each other via transistors T0A and T2B whose gates are connected to column selection lines CSL0 to CSL2.

FIG. 6B shows how “1” is written into memory cells C10, C01, C21, C02, and C12 randomly out of the memory cells C00 to C22 with arbitrary timing, and positive hole groups 9 are accumulated in the channel semiconductor layers 7 of the memory cells.

The refresh operation will be described using FIGS. 6C and 6D. Here, description will be given of a case in which the word line WL1 and the plate line PL₁ are selected by the row decoder circuit RDEC. In FIG. 6C, in the channel semiconductor layers 7 of the memory cells C01 and C21 written with “1,” a refresh operation is performed to form the positive hole groups 9 by the impact ionization phenomenon. The threshold voltages of the first gate conductor layer 5a and the second gate conductor layer 5b, in which the memory cells C01 and C21 are connected with the plate line PL1 and the word line WL1, drop as much as 1 V, for example, from 1.3 V in the 0-erased state to 0.3 V in the 1-written state. Therefore, if a voltage lower than the voltage for a “1” writing operation is input to the plate line PL1 and the word line WL1, a refresh operation can be performed to form the positive hole groups 9 by the impact ionization phenomenon in the channel semiconductor layers 7 of the memory cells C01 and C21. However, in FIG. 6D, it is assumed that the voltage of the channel semiconductor layers 7 of the memory cells C01 and C21 written with “1” has dropped slightly from the first data retention voltage V_{FB} “1” to V_{FB} “1”−ΔV_{FB}.

At time R1 in FIG. 6D, the transfer signal FT drops from a high voltage V_{FTH} to the low voltage Vss. At time R2, the word line WL1 is selected and the voltage rises from the low voltage Vss to the high voltage V_{WLR} for refreshing. Here, for example, the low voltage Vss may be 0 V and the high voltage V_{WLR} may be 1.3 V. Then, at time R3, when the bit line precharge signal FS rises from the low voltage Vss to a high voltage V_{FSH}, the bit lines BL0 to BL2 rise from the low voltage Vss to a high voltage V_{BLR} for refreshing. As a result, even if the number of the positive hole groups 9 has been reduced in the channel semiconductor layers 7 of the memory cells C01 and C21 written with “1,” the refresh operation raises the positive hole groups 9 to a built-in voltage Vb. Subsequently, when the word line WL1 is reset at time R4 and the bit lines BL0 to BL2 are reset at time R5, as a result of capacitive coupling among the word line WL1, the bit lines BL0 to BL2, and the channel semiconductor layers 7, the voltage of the channel semiconductor layers 7 drops slightly from Vb to become the first data retention voltage V_{FB} “1.”

FIG. 6E shows an example in which the row decoder circuit is equipped with an address latch circuit (which is an example of an “address latch circuit” described in Claims) LAT. Here, it is shown how multiple word lines WL0 and WL₂ are selected arbitrarily and the memory cells C10, C02, and C12 are subjected to a refresh operation.

FIG. 6F shows a case in which a select-all-word-lines signal (which is an example of a “select-all-word-lines signal” described in Claims) ALLWL is input to the row decoder circuit. Here, it is shown how all the word lines WL0 to WL2 in the memory cell block are selected and the memory cells C10, C01, C21, C02, and C12 are subjected to a refresh operation.

FIG. 6G shows an example in which a refresh operation is performed periodically using a temperature sensor circuit (which is an example of a “temperature sensor circuit” described in Claims) TEMP and a timer circuit (which is an example of a “timer circuit” described in Claims) TIMER.

FIG. 6H shows an example in which the plate line PL is shared by adjacent memory cells in a 3-row by 3-column block of memory cells C00 to C22. This configuration can also realize the refresh operation of the dynamic flash memory cell according to the first embodiment of the present invention.

In FIG. 1, operation of the dynamic flash memory described in the present embodiment can be performed even if a horizontal sectional shape of the Si pillar 2 is circular, elliptical, or rectangular. Besides, circular, elliptical, and rectangular dynamic flash memory cells may be allowed to coexist on a same chip.

In FIG. 1, a dynamic flash memory element has been described by taking as an example an SGT that includes the first gate insulating layer 4a surrounding an entire lateral surface of the Si pillar 2 erected in a vertical direction on a substrate, the second gate insulating layer 4b, and the first gate conductor layer 5a and second gate conductor layer 5b surrounding the entire first gate insulating layer 4a and second gate insulating layer 4b. As indicated in the description of the present embodiment, it is sufficient if the present dynamic flash memory element is structured to satisfy the condition that the positive hole groups 9 generated by the impact ionization phenomenon are held in the channel region 7. For that, it is sufficient that the channel region 7 has a floating body structure separated from the substrate 1. Consequently, the above-mentioned operation of the dynamic flash memory can be performed using, for example, GAA (Gate All Around; see, for example, Non Patent Literature 10) technology or Nanosheet technology (see, for example, Non Patent Literature 11), which are one of SGT even if the semiconductor base material of the channel region is formed horizontally to the substrate 1. A device structure (see, for example, Non Patent Literatures 7 to 10) that uses SOI (Silicon On Insulator) may also be used. In this device structure, a bottom of a channel region is in contact with an insulating layer of an SOI substrate and surrounds other channel regions while being surrounded by a gate insulating layer and an element separating insulating layer. In this structure, again the channel region has a floating body structure. In this way, it is sufficient if the dynamic flash memory element provided by the present embodiment satisfies the condition that the channel region has a floating body structure. Even with a structure in which a Fin transistor (see, for example, Non Patent Literature 13) is formed on an SOI substrate, the present dynamic flash operation can be performed as long as the channel region has a floating body structure.

Equations (1) to (12) in the present specification and drawings are used to quantitatively describe phenomena, and are not intended to limit the phenomena.

Note that whereas in the description of FIGS. 3AA-3AC and 3B, a reset voltage of the word line WL, the bit line BL, and the source line SL is indicated as being Vss, different reset voltages may be used for the different lines.

Besides, an example of conditions for the page erase operation has been shown in FIG. 4A and in the description of FIG. 4A. In contrast, if a situation in which the positive hole groups 9 in the channel region 7 are removed from both or one of the N⁺ layer 3a and N⁺ layer 3b can be realized, the voltages applied to the source line SL, the plate line PL, the bit line BL, and the word line WL may be changed. Also, in the page erase operation, the bit line BL may be placed in a floating state by applying a voltage to the source line SL of a selected page. Also, in the page erase operation, the source line SL may be placed in a floating state by applying a voltage to the bit line BL of a selected page.

Besides, in a vertical direction in FIG. 1, in that part of the channel region 7 which is surrounded by the insulating layer 6, which is the first insulating layer, potential distributions of a first channel region 7a and a second channel region 7b are formed by being joined together. Consequently, the first channel region 7a and the second channel region 7b of the channel region 7 are joined together in the vertical direction via a region surrounded by the insulating layer 6, which is the first insulating layer.

Note that in FIG. 1, desirably vertical length of the first gate conductor layer 5a connected with the plate line PL is made still larger than vertical length of the second gate conductor layer 5b connected with the word line WL such that C_{PL}>C_{WL}. However, by merely adding the plate line PL, a capacitive coupling ratio (C_{WL}/(C_{PL}+C_{WL}+C_{BL}+C_{SL})) of the word line WL to the channel region 7 is reduced. This reduces a potential fluctuation ΔV_{FB} in the channel region 7 of the floating body.

Whereas in an operation waveform diagram of FIG. 6D, voltages of the bit line BL, the word line WL, and the plate line PL are expressly indicated in a concrete manner, it is sufficient if voltage conditions are such that the impact ionization phenomenon can be caused in the channel region 7 using a memory cell current to perform the refresh operation and thereby form the positive hole groups 9.

Besides, a fixed voltage of, for example, approximately 1 V may be applied as the voltage V_{PLL} of the plate line PL.

Note that in the present specification and the claims, the expression “a gate insulating layer, a gate conductor layer, or the like covers a channel or the like,” the meanings of the term “covers” include surrounding an entire object such as in the case of an SGT or GAA, surrounding an object by leaving part of the object such as in the case of a Fin transistor, and furthermore lying over a planar object such as in the case of a planar transistor.

In FIG. 1, the first gate conductor layer 5a surrounds the entire first gate insulating layer 4a. In contrast, the first gate conductor layer 5a may be structured to surround part of the first gate insulating layer 4a in planar view. The first gate conductor layer 5a may be divided into at least two gate conductor layers and operated as electrodes of plate lines PL. Similarly, the second gate conductor layer 5b may be divided into two or more parts, each of which may be operated synchronously or asynchronously as a conductor electrode of a word line. This enables dynamic flash memory operation.

Whereas the refresh operation of a 1-bit dynamic flash memory cell made up of one piece of semiconductor base material has been described in FIGS. 6A to 6H, the present invention is also effective with respect to the refresh operation of a 1-bit high-speed dynamic flash memory cell made up of two pieces of semiconductor base material configured to store complementary data of “1” and “0.”

Whereas a page read operation of a memory array formed of a single layer of a 1-bit dynamic flash memory cell made up of one piece of semiconductor base material has been described in FIGS. 6A to 6F, the present invention is also effective with respect to a multi-layer memory array formed by stacking multiple tiers of 1-bit dynamic flash memory cells each made up of one piece of semiconductor base material.

Besides, in FIG. 1, the first gate conductor layer 5a may be divided into two or more parts, which may be operated synchronously or asynchronously, each as a conductor electrode of a plate line, by a same drive voltage or different drive voltages. Similarly, the second gate conductor layer 5b may be divided into two or more parts, which may be operated synchronously or asynchronously, each as a conductor electrode of a word line, by a same drive voltage or different drive voltages. This also enables dynamic flash memory operation. When the first gate conductor layer 5a is divided into two or more parts, at least one of the resulting first gate conductor layers serves the role of the first gate conductor layer 5a. Also, when the second gate conductor layer 5b is divided, at least one of the resulting second gate conductor layers serves the role of the second gate conductor layer 5b.

Besides, in FIG. 1, the first gate conductor layer 5a may be connected to the word line WL and the second gate conductor layer 5b may be connected to the plate line PL. This also enables the present dynamic flash memory operation described above.

Besides, the conditions of the voltages applied to the bit lines BL, the source lines SL, the word lines WL, and the plate lines PL as well as the voltage of the floating body are exemplary in performing basic operations including erase operations, write operations, and read operations, and other voltage conditions that allow the basic operations of the present invention to be performed may be used.

The present embodiment has the following features.

(Feature 1)

In the dynamic flash memory cell according to the present embodiment, the N⁺ layers 3a and 3b, which are to become the source and the drain, the channel region 7, the first gate insulating layer 4a, the second gate insulating layer 4b, the first gate conductor layer 5a, and the second gate conductor layer 5b are formed into the shape of a pillar as a whole. Then, the N⁺ layer 3a to become the source is connected to the source line SL, the N⁺ layer 3b to become the drain is connected to the bit line BL, the first gate conductor layer 5a is connected to the plate line PL, and the second gate conductor layer 5b is connected to the word line WL. The dynamic flash memory cell is characterized in that the gate capacitance of the first gate conductor layer 5a connected with the plate line PL is structured to be higher than the gate capacitance of the second gate conductor layer 5b connected with the word line WL. In the present dynamic flash memory cell, the first gate conductor layer and the second gate conductor layer are stacked in the vertical direction. Consequently, even if the gate capacitance of the first gate conductor layer 5a connected with the plate line PL is structured to be higher than the gate capacitance of the second gate conductor layer 5b connected with the word line WL the area of the memory cell is not increased in planar view. This makes it possible to achieve higher performance and greater packaging density of the dynamic flash memory cell at the same time.

(Feature 2)

The refresh operation of the dynamic flash memory cell according to the first embodiment of the present invention can return the positive hole groups 9 lost by leakage current and the like to a 1-written state again in the channel semiconductor layers 7 of the memory cell using the impact ionization phenomenon. The refresh operation can be performed simultaneously on the memory cells in a 1-written state selected by plural word lines or the word lines in an entire memory subarray and thereby reduce a total refresh time. Furthermore, by monitoring ambient temperature and making a refresh cycle variable, it is possible to deal with a situation in which the ambient temperature changes, increasing or decreasing the leakage current. This makes it possible to greatly improve the ratio of refresh time (duty ratio). Besides, it is possible to prevent write data of “1” from turning into “0” and thereby provide a highly reliable memory device.

(Feature 3)

Taking a look at the role of the first gate conductor layer 5a connected with the plate line PL of the dynamic flash memory cell according to the first embodiment of the present invention, when the dynamic flash memory cell performs write and read operations, the voltage of the word line WL swings up and down. In so doing, the plate line PL serves the role of reducing the capacitive coupling ratio between the word line WL and the channel region 7. This makes it possible to greatly reduce the effect of voltage variations of the channel region 7 when the voltage of the word line WL swings up and down. This in turn makes it possible to increase a difference in the threshold voltage of an SGT transistor of the word line WL, the difference representing logic “0” or logic “1.” This leads to an increase in an operating margin of the dynamic flash memory cell.

Besides, in writing “1,” using a gate induced drain leakage (GIDL) current described in Non Patent Literatures 10 and 11, electron-hole pairs may be generated by the impact ionization phenomenon and the floating body FB may be filled with generated positive hole groups. This similarly applies to other embodiments of the present invention.

Also, in FIG. 1, in a structure in which polarity of conductivity type of each of the N⁺ layers 3a and 3b and p-layer Si pillar 2 is reversed, the dynamic flash memory operation is performed. In this case, in the Si pillar 2, which is N-type, majority carriers become electrons. Thus, electron groups generated by impact ionization are accumulated in the channel region 7, and a “1” state is established.

### OTHER EMBODIMENTS

Note that whereas a Si pillar is formed in the present invention, a semiconductor pillar made of a semiconductor material other than Si may be used. This similarly applies to other embodiments of the present invention.

The present invention can be embodied or modified in various forms without departing from the spirit and scope of the present invention in a broad sense. Also, the embodiments described above are meant to be illustrative, and not to limit the scope of the present invention. The embodiments and variations described above can be combined as desired. Furthermore, even if some components of the embodiments described above are removed as required, the resulting inventions fall within the scope of the technical idea of the present invention.

### INDUSTRIAL APPLICABILITY

The memory device that uses a semiconductor element according to the present invention provides a dynamic flash memory, which is a memory device that uses a high-performance SGT with great packaging density.

1. A memory device that uses a semiconductor element in which a page is made up of a plurality of memory cells arranged in a row direction of a substrate, and a plurality of the pages is arranged in a column direction,
wherein each of the memory cells contained in each of the pages includes:
a semiconductor base material erected on the substrate in a vertical direction of the substrate or extended on the substrate in a horizontal direction,
a first impurity layer and a second impurity layer provided on opposite ends of the semiconductor base material,
a first gate insulating layer placed in contact with, or close to, the first impurity layer, partially or entirely surrounding a lateral surface of the semiconductor base material between the first impurity layer and the second impurity layer,
a second gate insulating layer joined to the first gate insulating layer and placed in contact with, or close to, the second impurity layer, surrounding the lateral surface of the semiconductor base material,
a first gate conductor layer covering part or all of the first gate insulating layer,
a second gate conductor layer covering the second gate insulating layer, and
a channel semiconductor layer in which the semiconductor base material is covered with the first gate insulating layer and the second gate insulating layer;
a page write operation and a page erase operation are performed by controlling voltages applied to the first gate conductor layer, the second gate conductor layer, the first impurity layer, and the second impurity layer;
the first impurity layer of the memory cell is connected with a source line, the second impurity layer is connected with a bit line, one of the first gate conductor layer and the second gate conductor layer is connected with a word line, and another is connected with a drive control line; and
at least one of word lines is selected and a refresh operation is performed to return a voltage of the channel semiconductor layer to a voltage just after the page write operation by controlling voltages applied to the selected word line, the drive control line, the source line, and the bit line and thereby forming positive hole groups by an impact ionization phenomenon in the channel semiconductor layer of the memory cell subjected to the page write operation.

2. The memory device that uses a semiconductor element according to claim 1, wherein during the refresh operation, at least one of the word lines is selected by an address latch circuit of a row decoder circuit.

3. The memory device that uses a semiconductor element according to claim 2, wherein during the refresh operation, a select-all-word-lines signal is input to the row decoder circuit to select all the word lines in the memory cell block.

4. The memory device that uses a semiconductor element according to claim 1, wherein the refresh operation is performed periodically.

5. The memory device that uses a semiconductor element according to claim 1, wherein the refresh operation is performed periodically using a temperature sensor circuit and a timer circuit.

6. The memory device that uses a semiconductor element according to claim 1, wherein the drive control line of the memory cells arranged in the row direction and in the column direction is disposed in common to adjacent ones of the memory cells.

7. The memory device that uses a semiconductor element according to claim 1, wherein first gate capacitance between the first gate conductor layer and the channel semiconductor layer is higher than second gate capacitance between the second gate conductor layer and the channel semiconductor layer.

8. The memory device that uses a semiconductor element according to claim 1, wherein when viewed in an axial direction of the semiconductor base material, the first gate conductor layer is separated into at least two conductor layers by surrounding the first gate insulating layer.

9. The semiconductor element memory device according to claim 1, wherein during the page write operation, a positive hole group generated by the impact ionization phenomenon is held in the channel semiconductor layer, and a voltage of the channel semiconductor layer is set to a first data retention voltage higher than a voltage/voltages of one or both of the first impurity layer and the second impurity layer; and
during the page erase operation, by controlling voltages applied to the first impurity layer, the second impurity layer, the first gate conductor layer, and the second gate conductor layer, the positive hole group is pulled out from one or both of the first impurity layer and the second impurity layer, and the voltage of the channel semiconductor layer is set to a second data retention voltage lower than the first data retention voltage.
